(19) United States
(12) Patent Application Publication
(10) Pub. No.: US 2026/0020449 A1
(43) Pub. Date: Jan. 15, 2026

(54) DISPLAY PANEL AND ELECTRONIC DEVICE COMPRISING THE SAME

(71) Applicant: Samsung Display Co., LTD., Yongin-si (KR)

(72) Inventor: Hyunae PARK, Yongin-si (KR)

(21) Appl. No.: 19/267,259

(22) Filed: Jul. 11, 2025

(30) Foreign Application Priority Data
Jul. 12, 2024 (KR) 10-2024-0092573

(51) Int. Cl. H10K 59/123; H10K 59/121; H10K 59/131

(52) U.S. Cl. CPC H10K 59/123; H10K 59/1213; H10K 59/131

(57) ABSTRACT

A display panel includes a substrate in which a display area including a pixel area and a peripheral area surrounding at least a part of the display area are defined, a first thin-film transistor disposed in the pixel area, where the first thin-film transistor includes a first semiconductor layer and a first gate electrode overlapping the first semiconductor layer, an initialization voltage line disposed on the first thin-film transistor and extending in a first direction, and a lower initialization voltage line disposed under the first thin-film transistor, extending in a second direction crossing the first direction and electrically connected to the initialization voltage line.

This application claims to Korean Patent Application No. 10-2024-0092573, filed on Jul. 12, 2024, and all the benefits accruing therefrom priority under 35 U.S.C. § 119, the content of which in its entirety is herein incorporated by reference.

### BACKGROUND

### 1. Field

One or more embodiments relate to a display panel.

### 2. Description of the Related Art

Display devices display data visually. Display devices may provide images using light-emitting diodes. The use of display devices becomes diversified, and various designs for enhancing the quality of display devices have been attempted.

### SUMMARY

One or more embodiments provide a display panel having enhanced reliability and quality. However, these embodiments are merely illustrative, and the scope of the disclosure is not limited thereto.

Additional aspects will be set forth in part in the description which follows and, in part, will be apparent from the description, or may be learned by practice of the embodiments of the disclosure set forth herein.

According to one or more embodiments, a display panel includes a display panel including a substrate in which a display area including a pixel area and a peripheral area surrounding at least a part of the display area are defined, a first thin-film transistor disposed in the pixel area, where first thin-film transistor includes a first semiconductor layer and a first gate electrode overlapping the first semiconductor layer, an initialization voltage line disposed on the first thin-film transistor and extending in a first direction, and a lower initialization voltage line disposed under the first thin-film transistor, extending in a second direction crossing the first direction and electrically connected to the initialization voltage line.

In an embodiment, the initialization voltage line and the lower initialization voltage line may be collectively in a mesh shape in a plan view.

In an embodiment, the display panel may further include a connection line disposed on the initialization voltage line.

In an embodiment, a first contact hole and a second contact hole may be defined in the connection line.

In an embodiment, the connection line may be electrically connected to the initialization voltage line through the first contact hole.

In an embodiment, an initialization voltage may be applied to the connection line through the first contact hole.

In an embodiment, the connection line may be electrically connected to the lower initialization voltage line through the second contact hole.

In an embodiment, the initialization voltage may be applied to the lower initialization voltage line through the second contact hole.

In an embodiment, the semiconductor layer may include a silicon semiconductor material.

In an embodiment, the display panel may further include a second thin-film transistor disposed between the first thin-film transistor and the connection line, where the second thin-film transistor includes a second semiconductor layer and a second gate electrode overlapping the second semiconductor layer.

In an embodiment, the second semiconductor layer may include an oxide semiconductor.

In an embodiment, the initialization voltage line may be disposed in a same layer as the second gate electrode of the second thin-film transistor.

According to one or more embodiments, a display panel includes a substrate including a display area and a peripheral area surrounding at least a part of the display area, a pixel circuit disposed in the display area of the substrate, where the pixel circuit includes an initialization transistor, an initialization voltage line disposed on the initialization transistor, being electrically connected to the initialization transistor and extending in a first direction, and a lower initialization voltage line disposed under the initialization transistor, extending in a second direction crossing the first direction and electrically connected to the initialization voltage line.

In an embodiment, the initialization voltage line and the lower initialization voltage line may be collectively in a mesh shape in a plan view.

In an embodiment, the display panel may further include a connection line disposed on the initialization transistor.

In an embodiment, a first contact hole, a second contact hole, and a third contact hole may be defined in the connection line.

In an embodiment, the connection line may be electrically connected to the initialization voltage line through the first contact hole, and an initialization voltage may be applied to the connection line through the first contact hole.

In an embodiment, the connection line may be electrically connected to the lower initialization voltage line through the second contact hole, and an initialization voltage may be applied to the lower initialization voltage line through the second contact hole.

In an embodiment, the connection line may be electrically connected to the initialization transistor through the third contact hole, and an initialization voltage may be applied to the initialization transistor through the third contact hole.

In an embodiment, the pixel circuit may further include a driving transistor and a switching transistor.

### BRIEF DESCRIPTION OF THE DRAWINGS

The above and other features of certain embodiments of the disclosure will be more apparent from the following description taken in conjunction with the accompanying drawings, in which:

FIG. 1 is a plan view schematically illustrating a display device according to an embodiment;

FIG. 2 is an equivalent circuit diagram of a pixel according to an embodiment;

FIG. 3 is a plan view schematically illustrating positions of elements that constitute a pixel according to an embodiment;

FIGS. 4 and 5 are plan views schematically illustrating a part of the elements of FIG. 3 according to layers;

FIG. 6 is a plan view illustrating a part of the elements that constitute a pixel shown in FIG. 3;

FIG. 7 is a plan view illustrating first through eighth transistors and a capacitor of a first pixel area as a part of FIG. 6;

FIGS. 8 and 9 are plan views schematically illustrating a part of the elements that constitute a pixel shown in FIG. 3 according to layers;

FIG. 10 is a cross-sectional view of the display panel, taken along lines I-I′ and II-II′ of FIG. 3; and

FIG. 11 is a cross-sectional view of the display panel, taken along line III-III′ of FIG. 3.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Since various modifications and various embodiments are possible, specific embodiments are illustrated in the drawings and described in detail in the detailed description. Effects and features of the disclosure, and a method of achieving them will be apparent with reference to embodiments described below in detail in conjunction with the drawings. However, the disclosure is not limited to the embodiments disclosed herein, but may be implemented in a variety of forms.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present.

In the drawings, for convenience of explanation, the sizes of elements may be exaggerated or reduced. For example, since the size and thickness of each component shown in the drawings are arbitrarily indicated for convenience of explanation, the disclosure is not necessarily limited to the illustration.

In the case where some embodiments may be implemented in the present specification, a specific process order may be performed differently from the order described. For example, two processes described in succession may be substantially performed at the same time, or in an opposite order to an order to be described.

In the following embodiments, when a layer, a region, a component, etc. are connected to each other, the layer, the region, and the components are directly connected to each other and/or the layer, the region, and the components may be indirectly connected to each other with other layers, other regions and other components interposed between the layer, the region, and the components. For example, when a layer, a region, a component, etc. are electrically connected to each other in the present specification, the layer, the region, the component, etc. are directly electrically connected to each other, and/or the layer, the region, the component, etc. are indirectly electrically connected to each other with other layers, other regions and other components interposed between the layer, the region, and the components.

The x-axis, the y-axis, and the z-axis are not limited to three axes on a Cartesian coordinate system, and may be interpreted in a broad sense including the same. For example, the x-axis, the y-axis, and the z-axis may be perpendicular to each other, but may refer to different directions that are not orthogonal to each other.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings, and the same or corresponding components are denoted by the same reference numerals, and the same reference numerals are assigned and any repetitive detailed description thereof will be omitted or simplified.

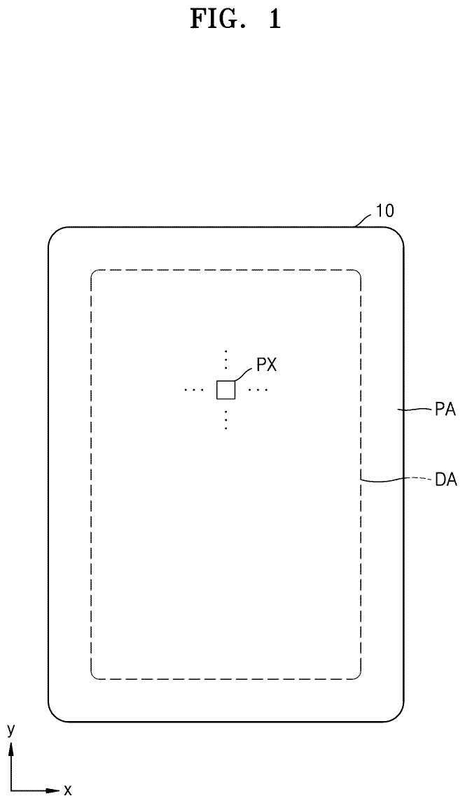

FIG. 1 is a plan view schematically illustrating a display device according to an embodiment.

Referring to FIG. 1, an embodiment of the display device may include a display panel 10, and a cover window (not shown) for protecting the display panel 10 may be further disposed on the display panel 10.

The display panel 10 may include a display area DA, in which images are displayed, and a peripheral area PA outside the display area DA. The peripheral area DPA may be a part of non-display area in which pixels PX are not arranged. In an embodiment, for example, the display area DA may be entirely surrounded by the peripheral area PA in a plan view. Various components that constitute the display panel 10 may be disposed on the substrate 100. Thus, it may be considered that the substrate 100 includes the display area DA and the peripheral area PA.

A plurality of pixels PX may be disposed in the display area DA. Each of the plurality of pixels PX may include a display element. The display element may be connected to a pixel circuit that drives the pixels PX. In an embodiment, the display element may be an organic light-emitting diode OLED. Each pixel PX may emit, for example, red, green, blue, or white light through the organic light-emitting diode OLED.

When the display area DA is viewed in a plan view, the display area DA may have approximately a rectangular shape as shown in FIG. 1. In another embodiment, the display area DA may be a polygonal shape, such as a triangle, a pentagon, a hexagon, etc., a circular shape, an oval shape, an atypical shape, or the like.

The peripheral area PA may be an area in the periphery of the display area DA and may be an area in which images are not displayed. Various conductive lines for transmitting electrical signals to be applied to the display area DA, outer circuits electrically connected to the pixel circuits, and pads to which a printed circuit board or a driver integrated circuit (IC) chip is attached, may be located in the peripheral area PA.

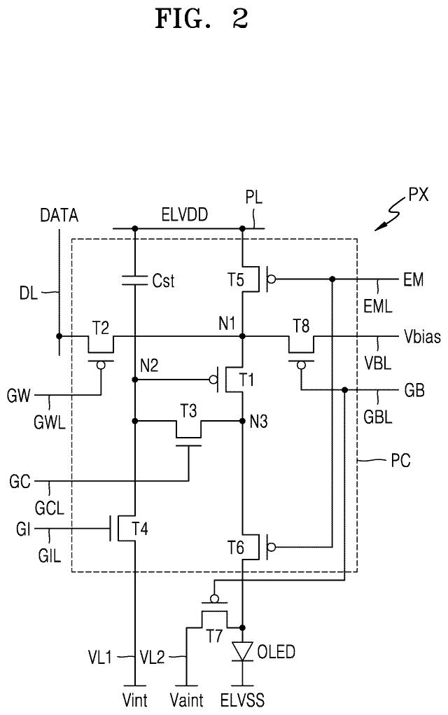

FIG. 2 is an equivalent circuit diagram of a pixel according to an embodiment.

Referring to FIG. 2, in an embodiment, each pixel PX may include a pixel circuit PC, and an organic light-emitting diode OLED as a display element connected to the pixel circuit PC. The pixel circuit PC may include a plurality of first to eighth transistors T1 through T8, a capacitor Cst, and signal lines connected thereto. The signal lines may include a data line DL, a first gate line GWL, a second gate line GCL, a third gate line GIL, a fourth gate line EML, a fifth gate line GBL, a first initialization voltage line VL1, a second initialization voltage line VL2, a driving voltage line PL, and a bias voltage line VBL.

The first gate line GWL, the second gate line GCL, the third gate line GIL, the fourth gate line EML, and the fifth gate line GBL may be gate control lines to which a gate signal for controlling turn-on and turn-off of the transistor is applied. The driving voltage line PL may transmit a driving voltage ELVDD to the first transistor T1. The driving voltage ELVDD may be a high-level voltage supplied to a pixel electrode (a first electrode or an anode) of the organic light-emitting diode OLED included in each pixel PX. The first initialization voltage line VL1 may transmit a first initialization voltage Vint1 for initializing the first transistor T1 to the pixel PX. The second initialization voltage line VL2 may transmit a second initialization voltage Vaint for initializing the organic light-emitting diode OLED to the pixel PX. The bias voltage line VBL may transmit a bias voltage Vbias to the first transistor T1.

The first transistor T1 may be a driving transistor, and the second through eighth transistors T2 through T8 may be switching transistors. In an embodiment, as shown in FIG. 2, the third transistor T3 and the fourth transistor T4 of the first through eighth transistors T1 through T8 may be N-type transistors and the remaining transistors thereof may be P-type transistors. According to the type (N-type or P-type) and/or operation conditions of the transistor, a first terminal of each of the first through eighth transistors T1 through T8 may be a source terminal or a drain terminal, and the second terminal thereof may be a terminal different from the first terminal. In an embodiment, for example, the first terminal is a source terminal, and the second terminal may be a drain terminal. In an embodiment, the source terminal and the drain terminal may be referred to interchangeably with a source electrode and a drain electrode, respectively.

The first transistor T1 may be connected between the driving voltage line PL and the organic light-emitting diode OLED. The first transistor T1 may be connected to the driving voltage line PL via the fifth transistor T5 and may be connected to the organic light-emitting diode OLED via the sixth transistor T6. The first transistor T1 may include a gate connected to a second node N2, a first terminal connected to a first node N1, and a second terminal connected to a third node N3. The first transistor T1 may supply a driving current to the organic light-emitting diode OLED by receiving a data signal based on a switching operation of the second transistor T2.

The second transistor T2 (a data write transistor) may be connected between the data line DL and the first node N1 and may be connected to the driving voltage line PL via the fifth transistor T5. The first node N1 may be a node in which the first transistor T1 and the fifth transistor T5 are connected to each other. The second transistor T2 includes a gate connected to the first gate line GWL, a first terminal connected to the data line DL, and a second terminal connected to the first node N1 (or the first terminal of the first transistor T1). The second transistor T2 may be turned on in response to the first gate signal GW transmitted through the first gate line GWL and may perform a switching operation of transmitting the data signal transmitted to the data line DL, to the first node N1.

The third transistor T3 (a compensation transistor) may be connected between the second node N2 and the third node N3. The third transistor T3 may be connected to the organic light-emitting diode OLED via the sixth transistor T6. The second node N2 may be a node to which a gate of the first transistor T1 is connected, and the third node N3 may be a node in which the first transistor T1 and the sixth transistor T6 are connected to each other. The third transistor T3 may include a gate connected to the second gate line GCL, a first terminal connected to the second node N2 (or the gate of the first transistor T1), and a second terminal connected to the third node N3 (or the second terminal of the first transistor T1). The third transistor T3 may be turned on in response to a second gate signal GC transmitted through the second gate line GCL and may diode-connect the first transistor T1, thereby compensating for a threshold voltage of the first transistor T1.

The fourth transistor T4 (a first initialization transistor) may be connected between the second node N2 and a first initialization voltage line VL1. The fourth transistor T4 may include a gate connected to the third gate line GIL, a first terminal connected to the second node N2, and a second terminal connected to the first initialization voltage line VL1. The fourth transistor T4 may be turned on in response to the third gate signal GI transmitted through the third gate line GIL to transmit the first initialization voltage Vint to a gate of the first transistor T1, thereby initializing the gate of the first transistor T1.

The fifth transistor T5 (a first emission control transistor) may be connected between the driving voltage line PL and the first node N1. The sixth transistor T6 (a second emission control transistor) may be connected between the third node N3 and the organic light-emitting diode OLED. The fifth transistor T5 may include a gate connected to a fourth gate line EML, a first terminal connected to the driving voltage line PL, and a second terminal connected to the first node N1. The sixth transistor T6 may include a gate connected to the fourth gate line EML, a first terminal connected to the third node N3, and a second terminal connected to a pixel electrode of the organic light-emitting diode OLED. The fifth transistor T5 and the sixth transistor T6 may be simultaneously turned on in response to the fourth gate signal EM transmitted through the fourth gate line EML such that a driving current flows through the organic light emitting diode OLED.

The seventh transistor T7 (a second initialization transistor) may be connected between the organic light-emitting diode OLED and the second initialization voltage line VL2. The seventh transistor T7 may include a gate connected to the fifth gate line GBL, a second terminal of the sixth transistor T6, a first terminal connected to the pixel electrode of the organic light emitting diode OLED, and a second terminal connected to the second initialization voltage line VL2. The seventh transistor T7 may be turned on in response to the fifth gate signal GB transmitted through the fifth gate line GBL to transmit the second initialization voltage Vaint to the pixel electrode of the organic light emitting diode OLED, thereby initializing the pixel electrode of the organic light emitting diode OLED.

The eighth transistor T8 (a bias transistor) may be connected between the first node N1 and the bias voltage line VB1. The eighth transistor T8 may include a gate connected to the fourth gate line EML, a first terminal connected to the bias voltage line VBL, and a second terminal connected to the first node N1. The eighth transistor T8 may be turned on in response to the fifth gate signal GB transmitted through the fifth gate line GBL, and may apply the bias voltage Vbias to the first terminal of the first transistor T1 to preset a voltage suitable for a subsequent operation of the first transistor T1 in the first terminal.

The capacitor Cst may include a first electrode and a second electrode. The first electrode may be connected to the gate of the first transistor T1, and the second electrode may be connected to the driving voltage line PL. The capacitor Cst may store and maintain a voltage corresponding to a voltage difference between the driving voltage line PL and both-end voltages of the gate of the first transistor T1, thereby maintaining a voltage applied to the gate of the first transistor T1.

The organic light-emitting diode OLED may include a pixel electrode and an opposite electrode, and a common voltage ELVSS may be applied to the opposite electrode. The common voltage ELVSS may be a low voltage supplied to the opposite electrode (a second electrode or a cathode) of the organic light-emitting diode OLED. The organic light-emitting diode OLED may receive a driving current IOLED from the first transistor T1 to emit light, thereby displaying an image.

In such an embodiment, at least one of the plurality of transistors T1 through T8 may include a semiconductor layer including an oxide, and the remaining transistors of the plurality of transistors T1 through T8 may include a semiconductor layer including silicon. In an embodiment, for example, a first transistor that directly affects brightness of the display device is configured to include a semiconductor layer including polycrystalline silicon having high reliability. Thus, the display device having high resolution may be implemented.

Since the oxide semiconductor has high carrier mobility and a low leakage current, voltage drop may not be large even when a driving time is long. That is, even when driving at low frequency is performed, a color change in an image due to voltage drop is not large, so that low frequency driving may be performed. As such, since the oxide semiconductor has less leakage current, at least one of the third transistor T3 and the fourth transistor T4 connected to the gate electrode of the first transistor T1 may be adopted as an oxide semiconductor to prevent a leakage current that may flow to the gate electrode of the first transistor T1 and simultaneously to reduce power consumption.

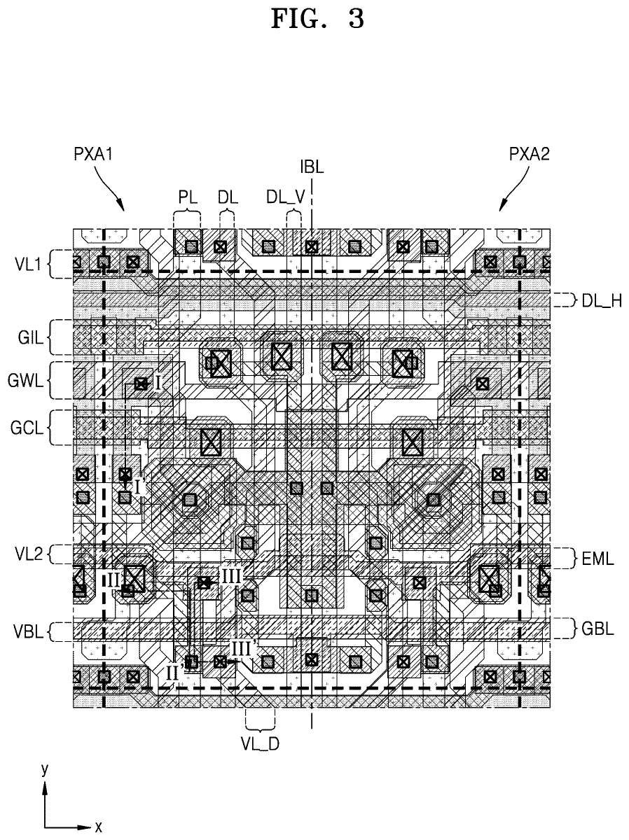

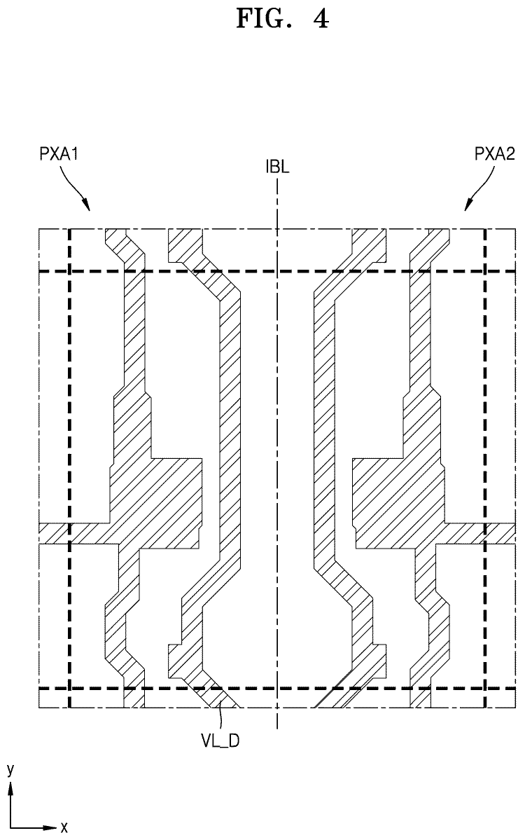

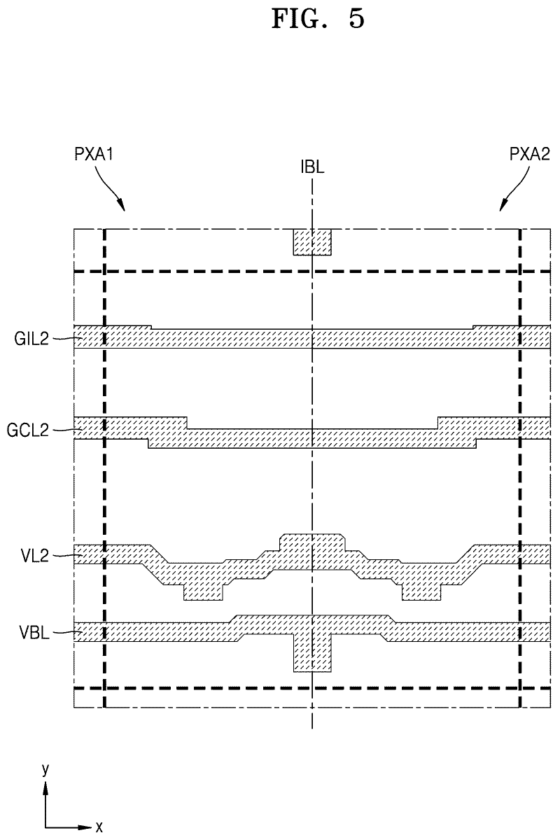

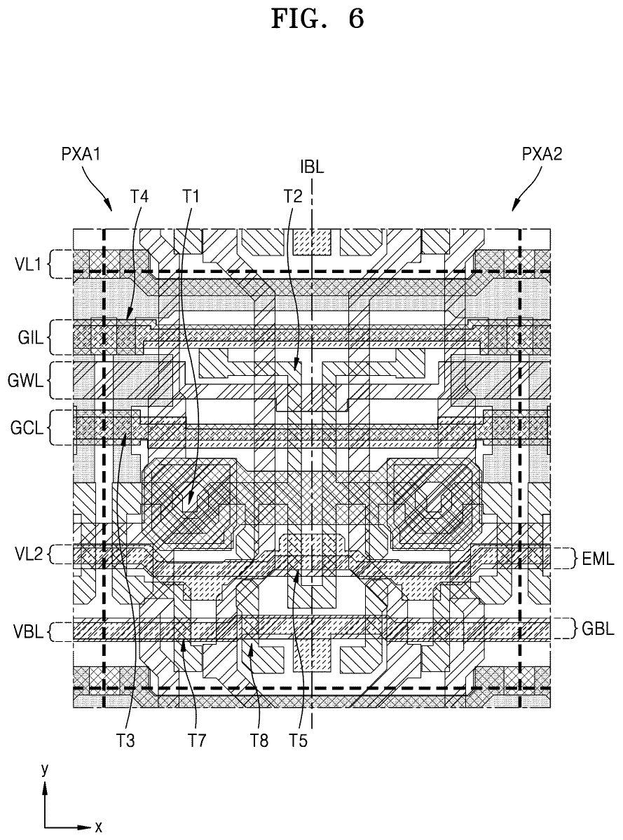

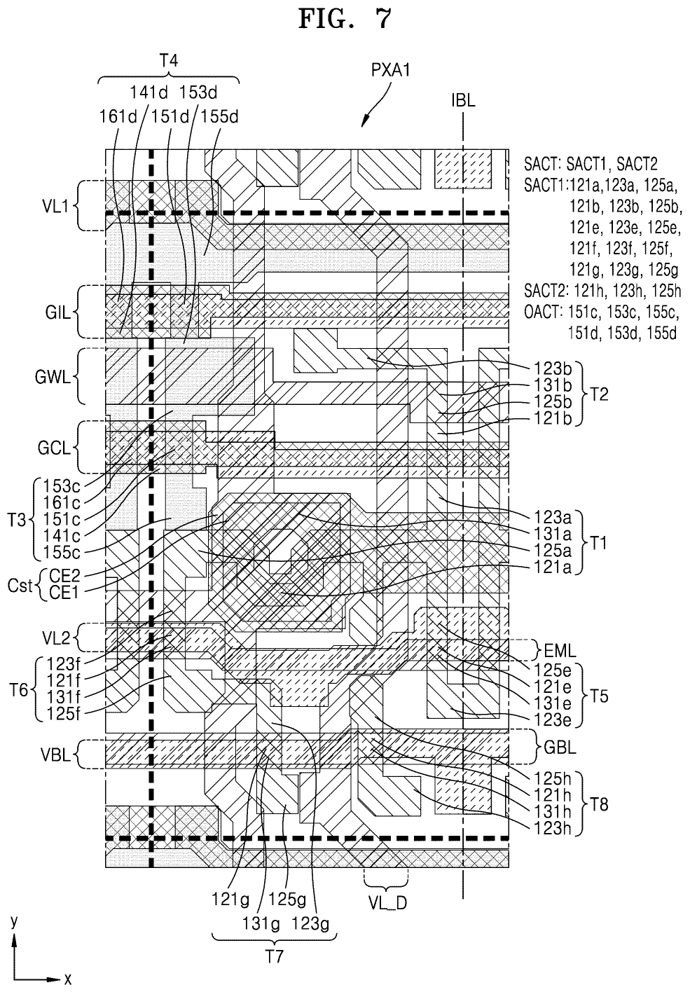

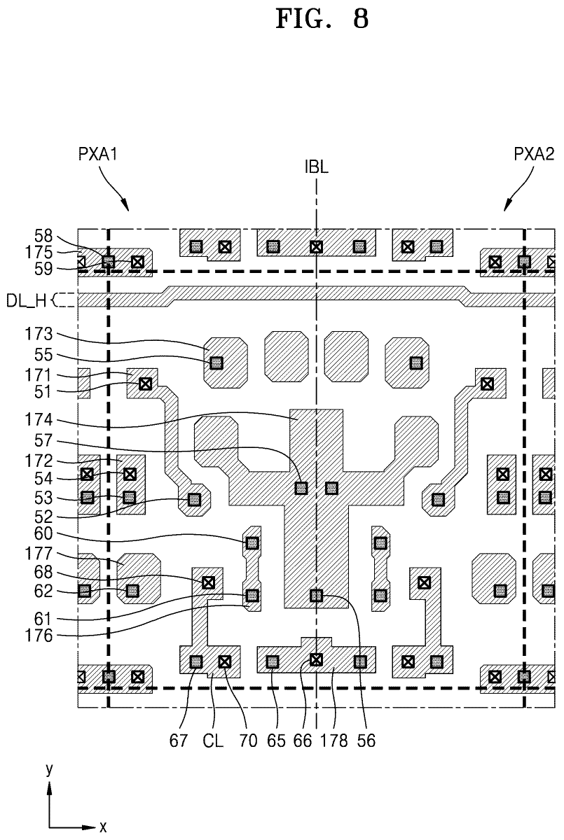

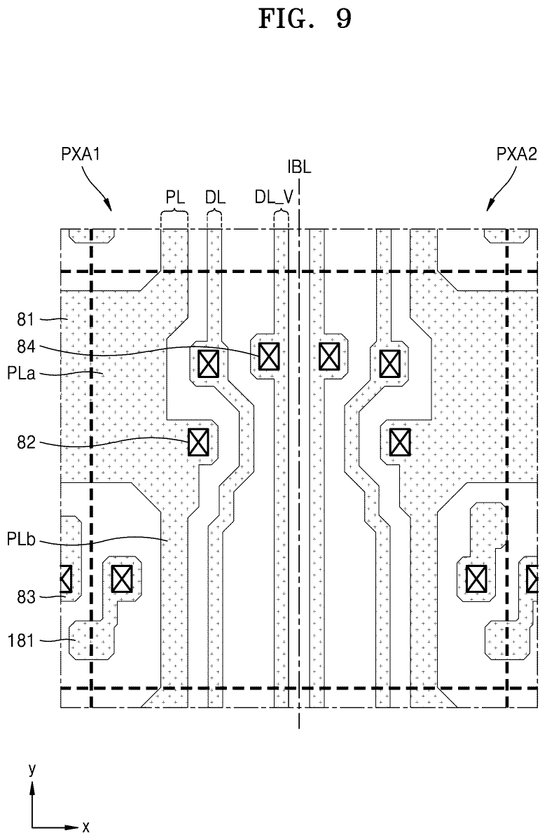

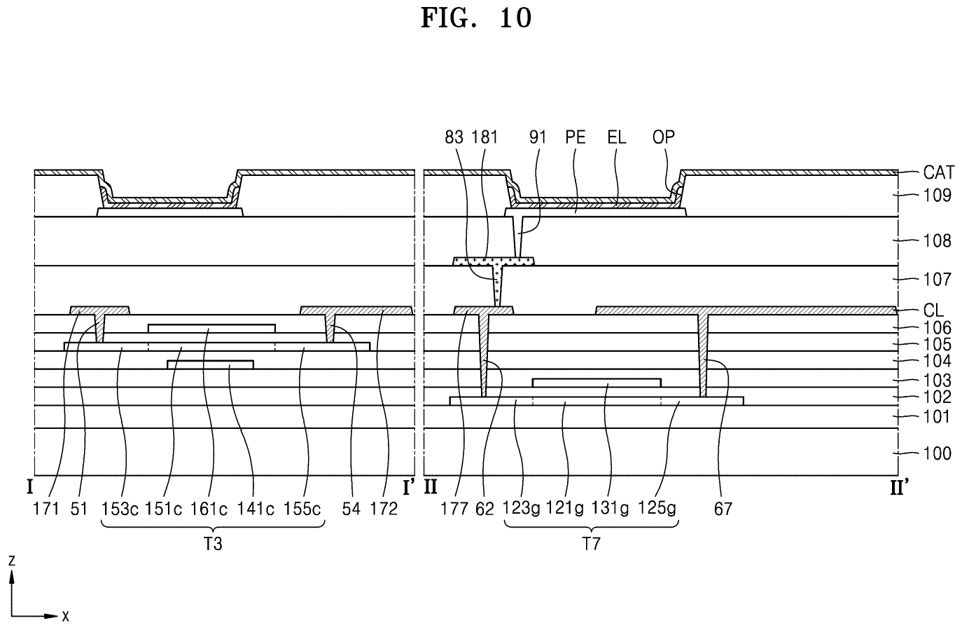

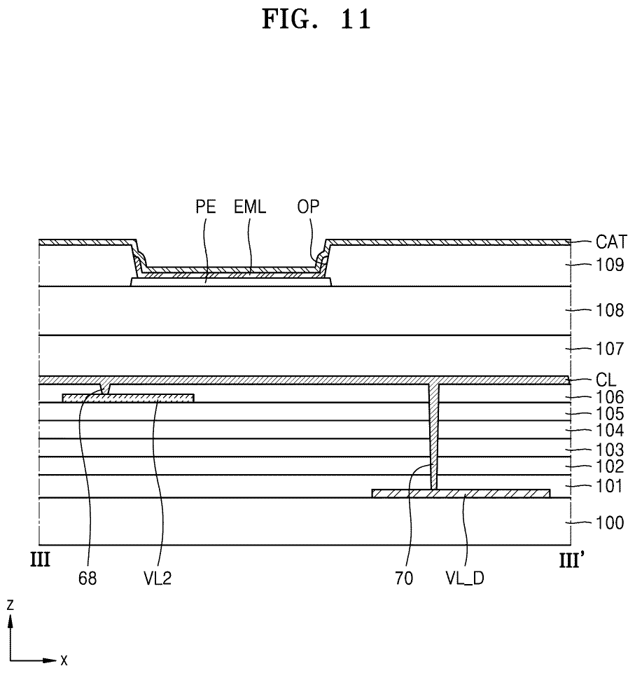

FIG. 3 is a plan view schematically illustrating positions of elements that constitute a pixel according to an embodiment. FIGS. 4 and 5 are plan views schematically illustrating a part of the elements that constitute a pixel shown in FIG. 3 according to layers. FIG. 6 is a plan view illustrating a part of elements that constitute a pixel according to an embodiment illustrated in FIG. 3. FIG. 7 is a part of FIG. 6 and is a plan view illustrating first through eighth transistors and a capacitor in a first pixel area. FIGS. 8 and 9 are plan views schematically illustrating a part of the elements that constitute a pixel shown in FIG. 3 according to layers. Specifically, FIGS. 8 and 9 are plan views schematically illustrating upper elements of FIG. 6 according to layers. FIG. 10 is a cross-sectional view of the display panel, taken along lines I-I′ and II-II′ of FIG. 3. FIG. 11 is a cross-sectional view of the display panel, taken along line III-III′ of FIG. 3.

In an embodiment, the display area DA defined on the substrate 100 may include a plurality of pixel areas where rows and columns cross each other. The pixel areas may be areas in which a pixel circuit is disposed. The pixel areas may include a pair of pixel areas including first pixel area PXA1 and second pixel area PXA2 adjacent to each other in the x-direction. A pixel circuit disposed in the first pixel area PXA1 and a pixel circuit disposed in the second pixel area PXA2 may be line-symmetric with respect to a boundary line IBL. Since the same elements are disposed in each layer of the first pixel area PXA1 and the second pixel area PXA2, elements of the pixel circuit disposed in the first pixel area PXA1 will be mainly described, for convenience of description. Hereinafter, elements of the pixel circuit disposed in the first pixel area PXA1 will be described with reference to FIGS. 4 through 11 together.

The substrate 100 may include a glass material, a ceramic material, a metal material, or a material having flexible or bendable characteristics. The substrate 100 may have a single layer structure of an organic layer or a multi-layered structure of an organic layer and an inorganic layer. In an embodiment, for example, the substrate 100 may have a stack structure of a first base layer/a barrier layer/a second base layer. Each of the first base layer and the second base layer may be an organic layer including polymer resin. The first base layer and the second base layer may include transparent polymer resin. The barrier layer that is a barrier layer for preventing penetration of external foreign substances may have a single layer or multi-layered structure including an inorganic material such as silicon nitride (SiNₓ) or silicon oxide (SiOₓ).

In an embodiment, as shown in FIG. 11, a lower initialization voltage line VL_D may be disposed between the substrate 100 and the buffer layer 101. The lower initialization voltage line VL_D may extend in the y-direction. In an embodiment, the lower initialization voltage line VL_D extending in the y-direction may be disposed in each of the first pixel area PXA1 and the second pixel area PXA2. The lower initialization voltage line VL_D disposed on the substrate 100 and extending in the y-direction, and the second initialization voltage line VL2 disposed on the fourth insulating layer 105 and extending in the x-direction may be provided in a mesh shape. In an embodiment, the second initialization voltage lines VL2 disposed in a plurality of pixel areas and extending in the x-direction and the lower initialization voltage lines VL_D disposed in the plurality of pixel areas and extending in the y-direction may be provided in a mesh shape.

In an embodiment, a barrier layer may be further included between the substrate 100 and the buffer layer 101. The barrier layer may have a single layer or multi-layered structure including an inorganic material such as silicon nitride (SiNₓ) or silicon oxide (SiOₓ).

The buffer layer 101 may be disposed on the lower initialization voltage line VL_D, and as shown in FIGS. 3 and 7, a first semiconductor layer SACT may be disposed on the buffer layer 101. The first semiconductor layer SACT may include a silicon semiconductor material. The first semiconductor layer SACT may include a first sub-semiconductor layer SACT1 and a second sub-semiconductor layer SACT2 separated from the first sub-semiconductor layer SACT1. The first sub-semiconductor layer SACT1 of the first pixel area PXA1 may be connected to the first sub-semiconductor layer SACT1 of the second pixel area PXA2 and may be integrally provided (or formed) as a single unitary indivisible part. The second sub-semiconductor layer SACT2 may be electrically connected to the first sub-semiconductor layer SACT1 as described later.

The first sub-semiconductor layer SACT1 may have a curved shape in various shapes. The first sub-semiconductor layer SACT1 may include a channel region of each of the first transistor T1, the second transistor T2, the fifth transistor T5, the sixth transistor T6, and the seventh transistor T7, a source region and a drain region at both opposing sides of the channel region. The second sub-semiconductor layer SACT2 may include a channel region, a source region, and a drain region of the eighth transistor T8.

Referring to FIG. 7, the first sub-semiconductor layer SACT1 may include a channel region 121a, a source region 123a and a drain region 125a of the first transistor T1, a channel region 121b, a source region 123b and a drain region 125b of the second transistor T2, a channel region 121e, source region 123e and a drain region 125e of the fifth transistor T5, a channel region 121f, a source region 123f and a drain region 125f of the sixth transistor T6, a channel region 121g, a source region 123g and a drain region 125g of the seventh transistor T7. The second sub-semiconductor layer SACT2 may include a channel region 121h, a source region 123h, and a drain region 125h of the eighth transistor T8.

The first insulating layer 102 may be disposed on the buffer layer 101 while covering the first semiconductor layer SACT, and as shown in FIGS. 7 and 10, the gate electrode 131a of the first transistor T1 may be disposed on the first insulating layer 102 in an island shape, and the first gate line GWL, the fourth gate line EML, and the fifth gate line GBL may be disposed on the first insulating layer 102 to extend in the x-direction.

Referring to FIG. 7, a gate electrode 131a of the first transistor T1 may be a lower electrode CE1 that is a first electrode of the capacitor Cst. A gate electrode 131b of the second transistor T2 may be defined by a part of the first gate line GWL crossing (overlapping) the first sub-semiconductor layer SACT1. A gate electrode 131e of the fifth transistor T5 and a gate electrode 131f of the sixth transistor T6 may be defined by parts of the fourth gate line EML crossing the first sub-semiconductor layer SACT1. A gate electrode 131g of the seventh transistor T7 may be defined by a part of the fifth gate line GBL crossing the first sub-semiconductor layer SACT1. A gate electrode 131h of the eighth transistor T8 may be defined by a part of the fifth gate line GBL crossing the second sub-semiconductor layer SACT2.

A second insulating layer 103 may be disposed on the first insulating layer 102, and, as shown in FIG. 3, the first initialization voltage line VL1, the lower gate line GIL1 of the second gate line GIL, and the lower gate line GCL1 of the third gate line GCL may be arranged on the second insulating layer 103 to extend in the x-direction. Also, an upper electrode CE2, which is the second electrode of the capacitor Cst, may be disposed in an island shape.

The upper electrode CE2, which is the second electrode of the capacitor Cst, may cover the lower electrode CE1 of the capacitor Cst. An opening SOP may be defined or formed in the upper electrode CE2 of the capacitor Cst.

A third insulating layer 104 may be disposed on the second insulating layer 103, and as shown in FIGS. 7 and 10, a second semiconductor layer OACT may be disposed on the third insulating layer 104. The second semiconductor layer OACT may include an oxide semiconductor. In other words, the second semiconductor layer OACT may include an oxide semiconductor material. The second semiconductor layer OACT may include a channel region, a source region, and a drain region of each of the third transistor T3 and the fourth transistor T4.

Referring to FIG. 7, the second semiconductor layer OACT may include a channel region 151c, a source region 153c, and a drain region 155c of the third transistor 3, a channel region 151d, a source region 153d, and a drain region 155d of the fourth transistor T4.

That is, it may be understood that a channel region, a source region and a drain region of each of the first through eighth transistors T1 through T8 may be defined by some regions of a semiconductor layer. A source region and a drain region of the semiconductor layer may correspond to a first terminal (or a second terminal) and a second terminal (or a first terminal) of the transistor, respectively, described above with reference to FIG. 2. The source region or the drain region may be interpreted as a source electrode or a drain electrode of the transistor in some cases. In an embodiment, for example, the source electrode and the drain electrode of the first transistor T1 may correspond to the source region 123a and the drain region 125a doped with impurities in the vicinity of the channel region 121a, respectively.

A fourth insulating layer 105 may be disposed on the third insulating layer 104, and as shown in FIG. 5, the upper gate line GIL2 of the second gate line GCL, the upper gate line GCL2, the second initialization voltage line VL2, and the bias voltage line VBL may be disposed on the fourth insulating layer 105 to extend in the x-direction.

In an embodiment, as described above, the second initialization voltage lines VL2 extending in the x-direction and the lower initialization voltage lines VL_D disposed on the substrate 100 and extending in the y-direction may be provided in a mesh shape. In an embodiment, the second initialization voltage lines VL2 disposed in a plurality of pixel areas and extending in the x-direction and the lower initialization voltage lines VL_D disposed in the plurality of pixel areas and extending in the y-direction may be provided in a mesh shape.

Referring to FIG. 7, the gate electrode of the third transistor T3 and the gate electrode of the fourth transistor T4 may be portions of the third gate line GCL crossing (overlapping) the second semiconductor layer OACT. The gate electrode of the third transistor T3 may include a lower gate electrode 141c that is a part of the lower gate line GCL1 of the third gate line GCL and an upper gate electrode 161c that is a part of the upper gate line GCL2. The gate electrode of the fourth transistor T4 may include a lower gate electrode 141d that is a part of the lower gate line GIL1 of the second gate line GIL and an upper gate electrode 161d that is a part of the upper gate line GIL2. That is, the third transistor T3 and the fourth transistor T4 may have a double gate structure including control electrodes on and under the second semiconductor layer OACT, respectively.

The bias voltage line VBL may overlap the fifth gate line GBL in a plan view.

A fifth insulating layer 106 may be disposed on the fourth insulating layer 105, and as shown in FIGS. 8 and 10, a horizontal data line DL_H may be disposed on the fifth insulating layer 106. Also, connection electrodes 171 through 178 and a connection line CL may be disposed on the fifth insulating layer 106. In other words, the connection line CL may be arranged on the second initialization voltage line VL2 and the seventh transistor (a second initialization transistor).

The connection line CL may be provided with contact holes 67, 88, and 70. The connection line CL may be electrically connected to the second initialization voltage line VL2 shown in FIG. 5 through the contact hole 68 defined or formed in the fifth insulating layer 106. A second initialization voltage Vaint may be applied to the connection line CL through the contact hole 68. The connection line CL to which the second initialization voltage Vaint is applied may be electrically connected to the drain region 125g of the seventh transistor T7 through the contact hole 67 defined or formed in the first through fourth insulating layers 102 through 105. The seventh transistor T7 may be a second initialization transistor. The second initialization voltage Vaint may be applied to the drain region 125g of the seventh transistor T7.

In an embodiment, the connection line CL may be electrically connected to the second initialization voltage line Vaint shown in FIG. 5 through the contact hole 68 defined or formed in the fifth insulating layer 106, and the second initialization voltage Vaint may be applied to the connection line CL through the contact hole 68. The connection line CL may be electrically connected to the lower initialization voltage line VL_D disposed between the substrate 100 and the buffer layer 101 through the buffer layer 101 and the contact hole 70 defined or formed in the first through fifth insulating layers 102 to 106. The second initialization voltage Vaint applied to the connection line CL through the contact hole 70 may be applied to the lower initialization voltage line VL_D. In other words, the lower initialization voltage line VL_D may be electrically connected to the second initialization voltage line Vaint through the connection line CL, and the second initialization voltage Vaint may be applied to the lower initialization voltage line VL_D.

In a case where the display panel does not include the lower initialization voltage line VL_D extending in the y-direction and includes only the second initialization voltage line VL2 extending in the x-direction, the resistance of the second initialization voltage line VL2 of the display panel is not sufficiently small and thus initialization according to the cycle of the GB signal of the second initialization voltage line VL2 is not sufficiently secured, and thus a horizontal line extending in the x-direction of the second initialization voltage line VL2 may be visually recognized, and the quality and reliability of the display device may be deteriorated.

In an embodiment, not only the second initialization voltage line VL2 extending in the x-direction but also the lower initialization voltage line VL_D extending in the y-direction are disposed the substrate 100 and the buffer layer 101, and the second initialization voltage line VL2 and the lower initialization voltage line VL2 are electrically connected to each other via the connection line CL, such that the resistance of the second initialization voltage line VL2 is sufficiently low and thus initialization according to the cycle of the GB signal of the second initialization voltage line VL2 is sufficiently secured, the quality and reliability of the display device may be improved. A process in which the lower initialization voltage line VL_D is disposed, is not significantly different from an existing process, and thus efficiency in a manufacturing process of the display panel may be increased.

One end of the connection electrode 171 may be in contact with a second semiconductor layer OACT through a contact hole 51 to be electrically connected to the second semiconductor layer OACT. One end of the connection electrode 171 may be electrically connected to the source region 153c of the third transistor T3 and the drain region 155d of the fourth transistor T4 through the contact hole 51 defined or formed in the fourth and fifth insulating layers 105 and 106. The other end of the connection electrode 171 may be electrically connected to the gate electrode 131a of the first transistor T1 through the contact hole 52 defined or formed in the second to fifth insulating layers 103 through 106. The contact hole 52 is disposed in the opening SOP of the capacitor Cst to be spaced apart from the edge of the opening SOP, such that the connection electrode 171 may be electrically insulated from the second electrode CE2.

The connection electrode 173 may be electrically connected to the source region 123b of the second transistor T2 through the contact hole 55 defined or formed in the first through fifth insulating layers 102 through 106.

The connection electrode 174 may be electrically connected to the source region 123e of the fifth transistor T5 through the contact hole 56 defined or formed in the first through fifth insulating layers 102 through 106. The connection electrode 174 may be electrically connected to the second electrode CE2 of the capacitor Cst through the contact hole 57 defined or formed in the third through fifth insulating layers 104 through 106.

The connection electrode 175 may be electrically connected to the first initialization voltage line VL1 through the contact hole 58 defined or formed in the second through fifth insulating layers 103 through 106. The connection electrode 175 may be electrically connected to the drain region 155d of the fourth transistor T4 through the contact hole 59 defined or formed in the fourth and fifth insulating layers 105 and 106.

The connection electrode 176 may be electrically connected to the source region 123c of the first transistor T1 and the drain region 125e of the fifth transistor T5 through the contact hole 60 defined or formed in the first through fifth insulating layers 102 through 106. The connection electrode 176 may be electrically connected to the drain region 125h of the eighth transistor T8 through the contact hole 61 defined or formed in the second to first through fifth insulating layers 102 through 106.

The connection electrode 177 may be electrically connected to the drain region 125f of the sixth transistor T6 through the contact hole 62 defined or formed in the first through fifth insulating layers 102 through 106.

The connection electrode 178 may be electrically connected to the source region 123h of the eighth transistor T8 through the contact hole 65 defined or formed in the first through fifth insulating layers 102 through 106. The connection electrode 178 may be electrically connected to the bias voltage line VBL through the contact hole 66 defined or formed in the fifth insulating layer 106.

A sixth insulating layer may be disposed on the fifth insulating layer, and as shown in FIGS. 9 and 10, a connection electrode 181 may be disposed on the sixth insulating layer, and the data line DL, the vertical data line DL_V, and the driving voltage line PL may be disposed to extend in the y-direction.

The data line DL may be electrically connected to the connection electrode 173 through a contact hole 81 defined or formed in the sixth insulating layer 107 to be electrically connected to the source region 123b of the second transistor T2.

The driving voltage line PL may include a substantially rectangular first portion PLa disposed in a pair of first pixel area PXA1 and second pixel area PXA2 adjacent to each other in the x-direction, and a substantially straight second portion PLb extending in the y-direction. The first portion PLa of the driving voltage line PL may be electrically connected to the connection electrode 174 through a contact hole 82 defined or formed in the sixth insulating layer 107 in the second pixel area PXA2.

The connection electrode 181 may be electrically connected to the connection electrode 172 through a contact hole 83 defined or formed in the sixth insulating layer 107 to be electrically connected to the source region 123f of the sixth transistor T6.

As illustrated in FIGS. 10 and 11, a seventh insulating layer 108 may be disposed on the sixth insulating layer 107, and a pixel electrode PE may be disposed on the seventh insulating layer 108. The pixel electrode PE may be electrically connected to the connection electrode 181 through a contact hole 91 defined or formed in the seventh insulating layer 108 to be electrically connected to the seventh transistor T7.

An eighth insulating layer 109, which is a pixel defining layer, may be disposed on the pixel electrode PE. The eighth insulating layer 109 may serve to define a pixel by an opening OP defined therethrough to correspond to an emission area of each pixel. An emission layer EL may be disposed in the opening OP of the eighth insulating layer 109, and an opposite electrode CAT may be disposed on the emission layer EL. The pixel electrode PE, the emission layer EL, and the opposite electrode CAT may constitute an organic light emitting diode. The opposite electrode CAT may be integrally formed in a plurality of organic light emitting diodes to correspond to a plurality of pixel electrodes PE. Although not shown, at least one functional layer may be further disposed on the upper and/or lower layers of the emission layer EL.

A thin film encapsulation layer (not shown) or a sealing substrate (not shown) may be disposed on the organic light emitting diode to cover the organic light emitting diode to protect the organic light emitting diode. The thin film encapsulation layer may include an inorganic encapsulation layer provided with at least one inorganic material and an organic encapsulation layer provided with at least one organic material. In some embodiments, the thin film encapsulation layer may be provided in a structure in which a first inorganic encapsulation layer/an organic encapsulation layer/a second inorganic encapsulation layer are stacked.

In an embodiment, not only the second initialization voltage line VL2 extending in the x-direction but also the lower initialization voltage line VL_D extending in the y-direction are disposed on the substrate 100 and the buffer layer 101, and the second initialization voltage line VL2 and the lower initialization voltage line VL_D are electrically connected to each other, such that the resistance of the second initialization voltage line VL2 is sufficiently low and thus initialization according to the cycle of the GB signal of the second initialization voltage line VL2 is sufficiently secured, the quality and reliability of the display device may be improved. A process in which the lower initialization voltage line VL_D is disposed, is not significantly different from an existing process, and thus efficiency in a manufacturing process of the display panel may be increased.

According to one or more embodiments described above, a display panel having enhanced reliability and quality can be implemented.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display panel comprising:
a substrate in which a display area including a pixel area and a peripheral area surrounding at least a part of the display area are defined;
a first thin-film transistor disposed in the pixel area, wherein first thin-film transistor comprises a first semiconductor layer and a first gate electrode overlapping the first semiconductor layer;
an initialization voltage line disposed on the first thin-film transistor and extending in a first direction; and
a lower initialization voltage line disposed under the first thin-film transistor, extending in a second direction crossing the first direction and electrically connected to the initialization voltage line.

2. The display panel of claim 1, wherein the initialization voltage line and the lower initialization voltage line are collectively in a mesh shape in a plan view.

3. The display panel of claim 1, further comprising a connection line disposed on the initialization voltage line.

4. The display panel of claim 3, wherein a first contact hole and a second contact hole are defined in the connection line.

5. The display panel of claim 4, wherein the connection line is electrically connected to the initialization voltage line through the first contact hole.

6. The display panel of claim 5, wherein an initialization voltage is applied to the connection line through the first contact hole.

7. The display panel of claim 6, wherein the connection line is electrically connected to the lower initialization voltage line through the second contact hole.

8. The display panel of claim 7, wherein the initialization voltage is applied to the lower initialization voltage line through the second contact hole.

9. The display panel of claim 1, wherein the first semiconductor layer comprises a silicon semiconductor material.

10. The display panel of claim 3, further comprising:
a second thin-film transistor disposed between the first thin-film transistor and the connection line, wherein the second thin-film transistor comprises a second semiconductor layer and a second gate electrode overlapping the second semiconductor layer.

11. The display panel of claim 10, wherein the second semiconductor layer comprises an oxide semiconductor material.

12. The display panel of claim 10, wherein the initialization voltage line is disposed in a same layer as the second gate electrode of the second thin-film transistor.

13. A display panel comprising:
a substrate comprising a display area and a peripheral area surrounding at least a part of the display area;
a pixel circuit disposed in the display area of the substrate, wherein the pixel circuit comprises an initialization transistor;
an initialization voltage line disposed on the initialization transistor, electrically connected to the initialization transistor and extending in a first direction; and
a lower initialization voltage line disposed under the initialization transistor, extending in a second direction crossing the first direction and electrically connected to the initialization voltage line.

14. The display panel of claim 13, wherein the initialization voltage line and the lower initialization voltage line are collectively in a mesh shape in a plan view.

15. The display panel of claim 13, further comprising a connection line disposed on the initialization transistor.

16. The display panel of claim 15, wherein a first contact hole, a second contact hole, and a third contact hole are defined in the connection line.

17. The display panel of claim 16, wherein the connection line is electrically connected to the initialization voltage line through the first contact hole, and an initialization voltage is applied to the connection line through the first contact hole.

18. The display panel of claim 17, wherein the connection line is electrically connected to the lower initialization voltage line through the second contact hole, and an initialization voltage is applied to the lower initialization voltage line through the second contact hole.

19. The display panel of claim 18, wherein the connection line is electrically connected to an initialization transistor through the third contact hole, and an initialization voltage is applied to the initialization transistor through the third contact hole.

20. An electronic device comprising:
a substrate in which a display area including a pixel area and a peripheral area surrounding at least a part of the display area are defined;
a first thin-film transistor disposed in the pixel area, and wherein first thin-film transistor comprising comprises a first semiconductor layer and a first gate electrode overlapping the first semiconductor layer;
an initialization voltage line disposed on the first thin-film transistor and extending in a first direction; and
a lower initialization voltage line disposed under the first thin-film transistor, extending in a second direction crossing the first direction and being electrically connected to the initialization voltage line.
